(19) United States
(12) Patent Application Publication
(10) Pub. No.: US 2024/0421000 A1
(43) Pub. Date: Dec. 19, 2024

(54) SEMICONDUCTOR DIE, SEMICONDUCTOR PACKAGE AND SUBSTRATE DICING METHOD

(71) Applicant: Samsung Electronics Co., Ltd., Suwon-si (KR)

(72) Inventors: YANGGYOO JUNG, Suwon-si (KR); YOUNG LYONG KIM, Suwon-si (KR); SUNGWOO PARK, Suwon-si (KR)

(21) Appl. No.: 18/392,481

(22) Filed: Dec. 21, 2023

(30) Foreign Application Priority Data
Jun. 15, 2023 (KR) 10-2023-0076851

(51) Int. Cl. H01L 21/78; H01L 23/00

(52) U.S. Cl. CPC H01L 21/78; H01L 23/564

(57) ABSTRACT

A semiconductor die includes: a first surface; a second surface opposite to the first surface; and a first side surface, a second side surface, a third side surface, and a fourth side surface between the first surface and the second surface, in which the first side surface faces the third side surface, and a roughness of the second side surface varies according to area, and a roughness of at least a portion of the second side surface is greater than that of the first side surface.

### CROSS-REFERENCE TO RELATED APPLICATION

This application claims priority to and the benefit of Korean Patent Application No. 10-2023-0076851 filed on Jun. 15, 2023, in the Korean Intellectual Property Office, the entire contents of which are incorporated herein by reference.

### BACKGROUND

### (a) Field of the Invention

The present disclosure relates to a semiconductor die, a semiconductor package, and a method of dicing a semiconductor die.

### (b) Description of the Related Art

Semiconductor manufacturing may be performed through various processes. For example, a process of cutting a wafer or the like may be included in a semiconductor manufacturing process. Wafers may be cut in a variety of ways. The wafer may be cut using a blade. The blade may be used to perform a dicing process in a straight line while moving from one end to the other end of the wafer.

### SUMMARY

The present disclosure is directed to a semiconductor die that may be produced with high productivity, a semiconductor package, and a substrate dicing method used for the same. However, the problems to be solved by the embodiments of the present disclosure are not limited to the above problems and can be variously extended within the scope of the inventive concept included in the present disclosure.

An according to an embodiment of the present disclosure, a semiconductor die includes: a first surface; a second surface opposite to the first surface; and a first side surface, a second side surface, a third side surface, and a fourth side surface between the first surface and the second surface, in which the first side surface faces the third side surface, and the second side surface faces the fourth side surface, and a roughness of the second side surface varies according to area, and a roughness of at least a portion of the second side surface is greater than that of the first side surface.

According to another embodiment of the present disclosure, there is provided a method of dicing a substrate including a plurality of semiconductor die arrays in which a plurality of the semiconductor dies are linearly arranged, a first dicing line parallel to a longitudinal direction of the plurality of semiconductor die arrays and a second dicing line intersecting the longitudinal direction of the plurality of semiconductor die arrays are located on outer circumferences of the plurality of semiconductor dies, the method including: performing a first dicing operation on the first dicing line using a first process; and performing a second dicing operation on the second dicing linen using a second process that is different from the first process.

According to still another embodiment of the present disclosure, a semiconductor package includes: a package substrate; an interposer mounted on the package substrate; and a semiconductor chip mounted on the interposer, in which the interposer includes: a first surface; a second surface located opposite to the first surface; and a first side surface, a second side surface, a third side surface, and a fourth side surface between the first surface and the second surface, and the first side surface faces the third side surface, and at least some area of the second side surface has cracks therein and has a roughness greater than that of the first side surface, and a roughness of the second side surface varies according to area.

According to embodiments, it may be possible to provide a semiconductor die that may be produced with high productivity, a semiconductor package, and a substrate dicing method used for the same.

### BRIEF DESCRIPTION OF THE DRAWINGS

FIG. 1 is a diagram illustrating a substrate on which a substrate dicing method according to some embodiments is performed.

FIG. 2 is a diagram illustrating a state in which a dicing process is performed on a first dicing line according to some embodiments.

FIG. 3 is a diagram illustrating a state in which a dicing process using a laser member is performed on a second dicing line according to some embodiments.

FIG. 4 is an enlarged view illustrating an area in which a dicing process using a laser member is performed on a second dicing line according to some embodiments.

FIG. 5 is a cross-sectional view illustrating a state in which a dicing process using a laser is performed inside a substrate according to some embodiments.

FIG. 6 is a diagram illustrating a tape expansion process, which is a last operation of the dicing process, according to some embodiments.

FIG. 7 is a diagram illustrating a semiconductor die diced by a substrate dicing method according to some embodiments.

FIG. 8 is a longitudinal cross-sectional view of a semiconductor die along a direction in which a first side surface and a third side surface face each other according to some embodiments.

FIG. 9 is a diagram illustrating a first side surface of a semiconductor die according to some embodiments.

FIG. 10 is a diagram illustrating a third side surface of a semiconductor die according to some embodiments.

FIG. 11 is a longitudinal cross-sectional view of a semiconductor die along a direction in which a second side surface and a fourth side surface face each other according to some embodiments.

FIG. 12 is a diagram illustrating a second side surface according to some embodiments.

FIG. 13 is a diagram illustrating a substrate on which a substrate dicing method according to further embodiments is performed.

FIG. 14 is a diagram illustrating a semiconductor die located at an end portion of a center-side semiconductor die array in a longitudinal direction among semiconductor dies diced by a substrate dicing method according to further embodiments.

FIG. 15 is a diagram illustrating a first side surface of a semiconductor die according to some embodiments.

FIG. 16 is a diagram illustrating a second side surface of a semiconductor die according to some embodiments.

FIG. 17 is a diagram illustrating a third side surface of a semiconductor die according to some embodiments.

FIG. 18 is a diagram illustrating a fourth side surface of a semiconductor die according to some embodiments.

FIG. 19 is a diagram illustrating a semiconductor package according to some embodiments.

### DETAILED DESCRIPTION OF THE EMBODIMENTS

Hereinafter, embodiments of the present disclosure will be described in detail with reference to the accompanying drawings so that those skilled in the art to which the present disclosure pertains may easily practice the embodiments of the present disclosure.

However, embodiments of the present disclosure may be implemented in various different forms and is not limited to embodiments provided herein.

Portions unrelated to the description will be omitted to clearly describe the embodiments of the present disclosure, and similar components will be denoted by the same or similar reference numerals throughout the present specification.

In addition, the size and thickness of each component illustrated in the drawings are arbitrarily indicated for convenience of description, and the present disclosure is not necessarily limited to the illustrated examples. In the drawings, the thickness of layers, regions, etc., are exaggerated for clarity. In addition, in the accompanying drawings, thicknesses of some of layers and regions have been exaggerated for convenience of explanation.

In addition, it will be understood that when an element such as a layer, film, region, or substrate is referred to as being “on” another element, it can be “directly on” the other element or intervening elements may also be present. In contrast, when an element is referred to as being “directly on” another element, there are no intervening elements present.

In addition, when an element is referred to as being “on” a reference element, it can be positioned on or beneath the reference element, and is not necessarily positioned on the referenced element in an opposite direction to gravity.

In addition, unless explicitly described to the contrary, the word “comprise”, and variations such as “comprises” or “comprising”, will be understood to imply the inclusion of other elements but not the exclusion of any other elements.

Further, throughout the specification, the word “plan view” refers to a view when a target is viewed from the top, and the word “cross-sectional view” refers to a view when a cross section of a target taken along a vertical direction is viewed from the side.

As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination

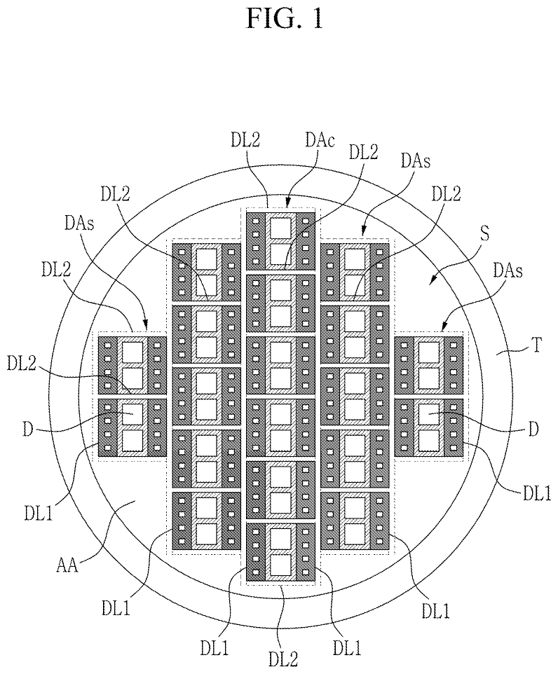

FIG. 1 is a diagram illustrating a substrate on which a substrate dicing method according to some embodiments is performed.

Referring to FIG. 1, a substrate S is provided in a state in which a plurality of semiconductor dies D are arranged.

A substrate S may be provided in a state in which it is attached to a tape T. The tape T may expand when an external force is applied.

The substrate S includes a plurality of semiconductor die arrays DAc and DAs. The semiconductor die arrays DAc and DAs are provided in a state in which a plurality of semiconductor dies D are linearly arranged. A boundary between the semiconductor dies D included in one semiconductor die array DAc and DAs is provided to intersect the longitudinal direction of the semiconductor die array DAc and DAs. For example, the boundary between the semiconductor dies D included in one semiconductor die array DAc and DAs may have an angle of about 90° with respect to the longitudinal direction of the semiconductor die array DAc and DAs.

A discard area AA is located outside the area in which the semiconductor die arrays DAc and DAs are arranged in the substrate S. The discard area AA is an area in which one semiconductor die D cannot be accommodated therein. Accordingly, the discard area AA is discarded after completion of the dicing process.

A plurality of semiconductor die arrays DAc and DAs may be arranged side by side with each other. The plurality of semiconductor die arrays DAc and DAs include a center-side semiconductor die array DAc and side semiconductor die arrays DAs.

A center-side semiconductor die array DAc is located across the central area of the substrate S. Both ends of the center-side semiconductor die array DAc may be located adjacent to an edge of the substrate S, respectively. FIG. 1 illustrates a case in which the center-side semiconductor die array DAc includes six semiconductor dies D. The number of semiconductor dies D included in the center-side semiconductor die array DAc may vary depending on the size of the semiconductor die D.

The side semiconductor die arrays DAs are located on both sides of the center-side semiconductor die array DAc, respectively. The number of semiconductor dies D included in the side semiconductor die array DAs may be less than the number of semiconductor dies D included in the center-side semiconductor die array DAc. The number of side semiconductor die arrays DAs arranged on one side of the center-side semiconductor die array DAc may be one or plural. When the plurality of side semiconductor die arrays DAs are located on one side of the center-side semiconductor die array DAc, the number of semiconductor dies D included in the side semiconductor die arrays DAs adjacent to each other may be different from each other. For example, the number of semiconductor dies D included in the side semiconductor die arrays DAs may decrease as the distance from the center-side semiconductor die array DAc increases. FIG. 1 illustrates an example in which two side semiconductor die arrays DAs are arranged on both sides of the center-side semiconductor die array DAc, respectively.

Dicing lines DL1 and DL2 are located around the outer circumference of each semiconductor die D. The dicing lines DL1 and DL2 include a first dicing line DL1 and a second dicing line DL2.

The first dicing line DL1 is provided parallel to the longitudinal direction of the semiconductor die arrays DAc and DAs. The first dicing line DL1 is provided on both sides of each of the semiconductor die arrays DAc and DAs along the direction in which the semiconductor die arrays DAc and DAs are arranged. Accordingly, a partial section of the first dicing line DL1 may be located between the semiconductor die arrays DAc and DAs adjacent to each other. In addition, the first dicing line DL1 may be located along the longitudinal direction of the side semiconductor die array DAs in a direction facing the edge of the substrate S in the side semiconductor die array DAs located on the outermost side.

The second dicing line DL2 is provided to intersect the longitudinal direction of the semiconductor die arrays DAc and DAs. The plurality of second dicing lines DL2 are provided in the semiconductor die arrays DAc and DAs, respectively. The second dicing line DL2 is located between the semiconductor dies D facing each other along the longitudinal direction of the semiconductor die arrays DAc and DAs. Also, the second dicing line DL2 may be located at both ends of each of the semiconductor die arrays DAc and DAs in the longitudinal direction.

The second dicing line DL2 may be located discontinuously between the semiconductor die arrays DAc and DAs adjacent to each other. Accordingly, one end of the second dicing line DL2 of one semiconductor die array DAc or DAs may be connected to the first dicing line DL1. That is, one end of the second dicing line DL2 located on one semiconductor die array DAc and DAs is provided to face the semiconductor die D located on the semiconductor die array DAc and DAs adjacent to each other.

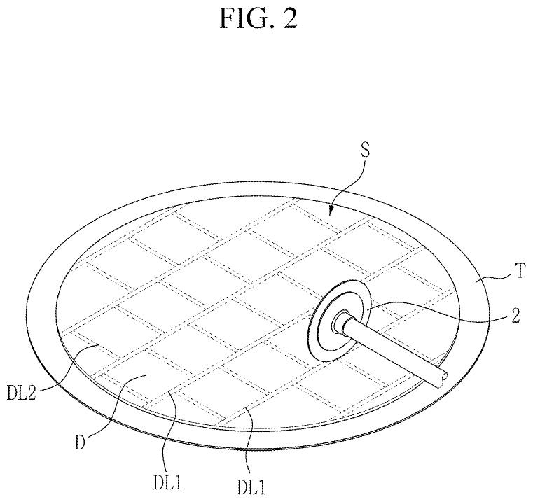

FIG. 2 is a diagram illustrating a state in which a dicing process is performed on a first dicing line according to some embodiments.

Referring to FIG. 2, the first dicing line DL1 may be diced using a blade 2. The blade 2 may be provided to rotate about a central area as an axis. The blade 2 may rotate while also moving along the first dicing line DL1 to dice the substrate S along the first dicing line DL1. That is, the blade 2 may move along the first dicing line DL1 while rotating. Also, the substrate S may move in a direction parallel to the first dicing line DL1 while the rotating blade 2 is located on the first dicing line DL1. In addition, the rotating blade 2 may move along the first dicing line DL1, and the substrate S may move parallel to the first dicing line DL1 in a direction opposite to the direction in which the blade 2 moves. Accordingly, the dicing process for the first dicing line DL1 may be continuously performed over an area including the plurality of semiconductor dies D.

The above-described dicing process for the first dicing line DL1 may be sequentially performed. For example, when the dicing process for one first dicing line DL1 is completed, the blade 2 is located to be spaced upward from the upper surface of the substrate S. Thereafter, the blade 2 moves relative to the substrate S in a direction intersecting the first dicing line DL1, To vertically align with the first dicing line DL1 on which no dicing is performed. Also, the blade 2 may perform a dicing process on a new first dicing line DL1 through the above-described process.

Also, the dicing process for the first dicing line DL1 may be simultaneously performed or synchronously performed on the plurality of first dicing lines DL1.

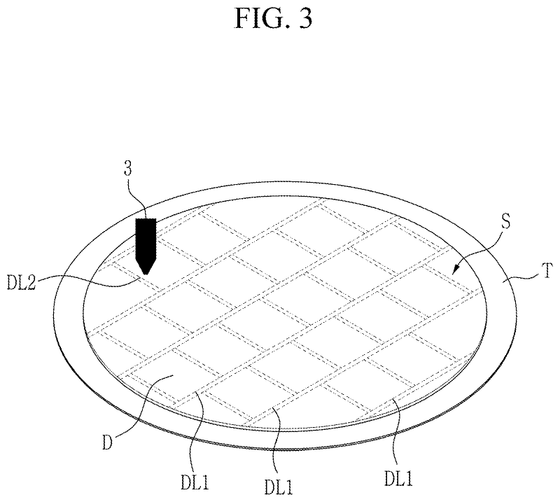

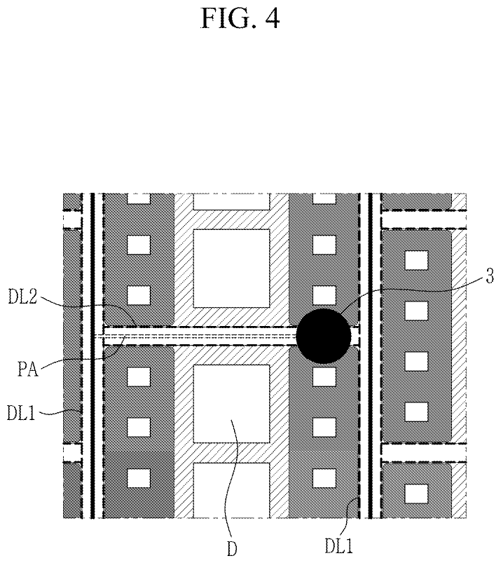

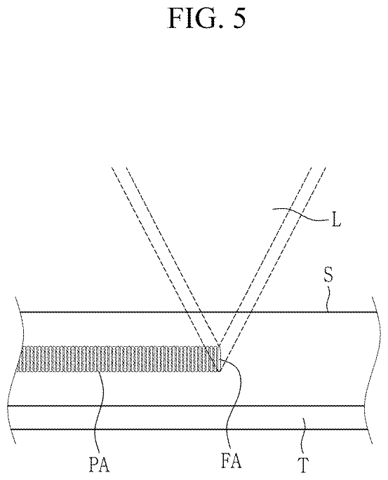

FIG. 3 is a diagram illustrating a state in which a dicing process using a laser member is performed on a second dicing line according to some embodiments. FIG. 4 is an enlarged view illustrating a state in which a dicing process using a laser member is performed on a second dicing line according to some embodiments. FIG. 5 is a cross-sectional view illustrating a state in which a dicing process using a laser is performed inside a substrate according to some embodiments.

Referring to FIGS. 3 to 5, the second dicing line DL2 may be diced by using the laser member 3.

The laser member 3 irradiates the laser L toward the substrate S, so the dicing process is performed on the substrate S. The position of the laser member 3 relative to the substrate S is provided to be adjustable, so that the position of the laser member 3 may be moved along the second dicing line DL2.

The laser L irradiated by the laser member 3 may be a pulse laser. The laser member 3 may irradiate the laser L in a form focused on the inside of the substrate S. Accordingly, an area FA in which the laser L is focused is formed inside the substrate S. In addition, the laser member 3 may irradiate the laser L in the form in which the area FA where the irradiated laser L is focused inside the substrate S has a predetermined height vertically as shown in FIG. 5. For example, the laser member 3 may be provided so that two or more lasers L may be irradiated at the same time at positions focused inside the substrate S spaced apart along the thickness direction of the substrate S.

The dicing process is performed on the substrate S by using the focused laser L to form a crack occurrence area PA. The crack occurrence area PA is provided as a crack formed in the substrate S.

Specifically, the energy applied by the laser L focused inside the substrate S forms a crack in the substrate S. The crack may have a shape corresponding to the area FA where the laser L is focused.

As the laser member 3 moves relative to the substrate S along the second dicing line DL2, the area FA on which the laser L is focused moves along the second dicing line DL2 inside the substrate S. Also, the crack occurrence area PA in which a crack occurs due to the focused laser L moves along the second dicing line DL2 inside the substrate S. The cracks overlap or are located adjacent to each other to form the crack occurrence area PA along the second dicing line DL2.

In the substrate S, a first dicing process may be performed for the first dicing line DL1 using the blade 2 and then a second dicing process may be performed on the second dicing line DL2 using the laser member 3. In this case, the laser member 3 may irradiate the laser L so that the area FA where the laser L is focused at both ends of the second dicing line DL2 overlaps the area where the dicing is performed by the blade 2. Accordingly, both ends of the crack occurrence area PA formed by the focused laser L may be connected to the area where the dicing is performed by the blade 2.

Further, in the substrate S, the dicing process may be performed on the second dicing line DL2 using the laser member 3 and then performed on the first dicing line DL1 using the blade 2. In this case, the laser member 3 may irradiate the laser L so that the area FA where the laser L is focused at both ends of the second dicing line DL2 overlaps the first dicing line DL1. Accordingly, both ends of the crack occurrence area PA formed by the focused laser L may be located to be connected to the first dicing line DL1. Thereafter, the blade 2 may perform dicing on the first dicing line DL1 to be connected to both ends of the crack occurrence area PA.

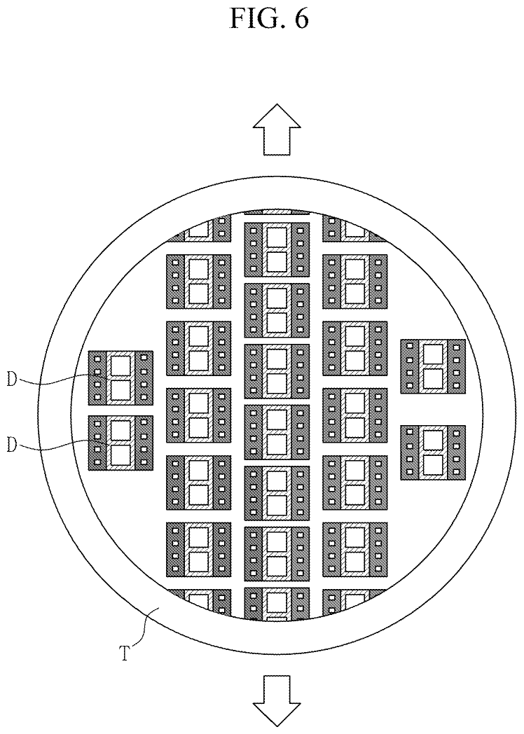

FIG. 6 is a diagram illustrating a tape expansion process, which may be a last operation of the dicing process, according to some embodiments.

Referring to FIG. 6, a tape expansion process is performed through expansion of the tape T. Specifically, the tape T may expand by a force applied in a direction toward the outside or toward the perimeter of the substrate S from a central area. In this case, the tape T may expand in a direction parallel to the first dicing line DL1 by a force applied in a direction parallel to the first dicing line DL1. In addition, the tape T may expand in both a direction parallel with the first dicing line DL1 and a direction intersecting the first dicing line DL1 by force applied in a direction parallel to the first dicing line DL1 and in a direction intersecting the first dicing line DL1.

The tape T applies force to the substrate S while expanding. The force applied to the substrate S acts in a direction in which the semiconductor dies D adjacent to the second dicing line DL2 where the crack occurrence area PA is formed are far away from each other. Accordingly, the cracks in the crack occurrence area PA propagate to the upper and lower surfaces of the substrate S, so the semiconductor dies D adjacent to each other are separated with the second dicing line DL2 interposed therebetween.

Also, the second dicing line DL2 is located between the first dicing lines DL1 adjacent to each other. Accordingly, both ends of the crack occurrence area PA formed in the second dicing line DL2 are each located in an area where the substrate S is diced along the first dicing line DL1. When the tape T expands, the area where the substrate S is diced along the first dicing line DL1 reduces or minimizes the force generated in the direction opposite to the expansion direction of the tape T. Accordingly, a force acting in a direction in which the semiconductor dies D adjacent to each other move away from each other is effectively applied to the crack occurrence area PA, so that the crack propagation toward the surface of the substrate S and the separation of the semiconductor dies D may be performed effectively.

In the substrate dicing method according to an embodiment, the dicing process may be performed on a substrate S designed to increase or maximize the number of semiconductor dies D arranged therein. Specifically, in the substrate S to be diced by the substrate dicing method according to an embodiment, the second dicing line DL2 may be discontinuously located between semiconductor die arrays DAc and DAs adjacent to each other.

Accordingly, the positions of both ends of each of the semiconductor die arrays DAc and DAs in the longitudinal direction may be adjusted to increase or maximize the number of semiconductor dies D arranged along the longitudinal direction. That is, each of the semiconductor die arrays DAc and DAs is arranged in such a way as to increase or maximize the number of semiconductor dies D arranged along the longitudinal direction without being affected by the positions of the adjacent semiconductor die arrays DAc and DAs. Accordingly, the plurality of semiconductor die arrays DAc and DAs may be arranged so that the semiconductor die D located inside the substrate S is increased or maximized. Also, the plurality of semiconductor die arrays DAc and DAs may be arranged so that the discard area AA is reduced or minimized.

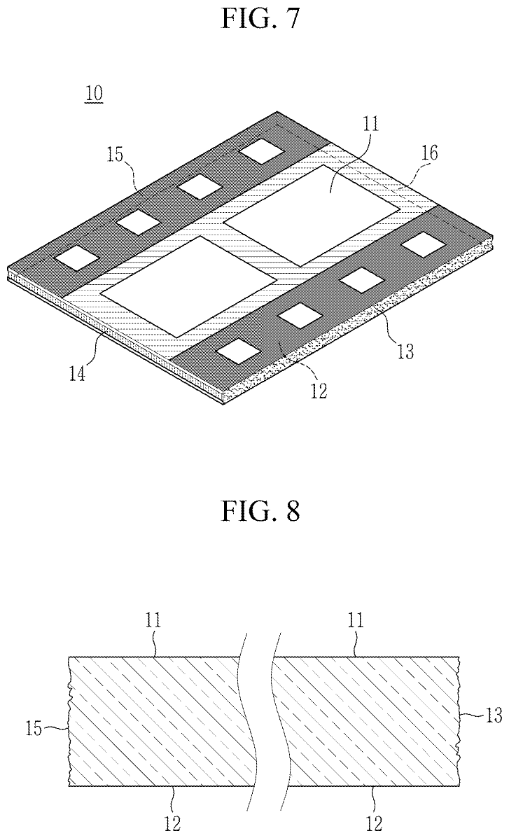

FIG. 7 is a diagram illustrating a semiconductor die diced by a substrate dicing method according to an embodiment.

Referring to FIG. 7, the semiconductor die 10 has a first surface 11 and a second surface 12 disposed to face each other in opposite directions. A first side surface 13, a second side surface 14, a third side surface 15, and a fourth side surface 16 may be located between the first surface 11 and the second surface 12. The first side surface 13 and the third side surface 15 may be located to face each other. The second side surface 14 and the fourth side surface 16 may be located to face each other. An outer side of the first side surface 13 may contact the first surface 11, the second surface 12, the second side surface 14, and the fourth side surface 16, respectively. An outer side of the second side surface 14 may contact the first surface 11, the second surface 12, the first side surface 13, and the third side surface 15, respectively. An outer side of the third side surface 15 may contact the first surface 11, the second surface 12, the second side surface 14, and the fourth side surface 16, respectively. An outer side of the fourth side surface 16 may contact the first surface 11, the second surface 12, the third side surface 15, and the first side surface 13, respectively.

The first side surface 13 and the third side surface 15 are areas facing the first dicing line DL1 in the substrate S described above. Accordingly, the first side surface 13 and the third side surface 15 are surfaces formed through the dicing process using the blade 2.

The second side surface 14 and the fourth side surface 16 are areas facing the second dicing line DL2 in the substrate dicing method described above. Accordingly, the second side surface 14 and the fourth side surface 16 are surfaces formed in a dicing process using the laser member 3 and an expansion process of the tape T and the substrate S attached to the tape T.

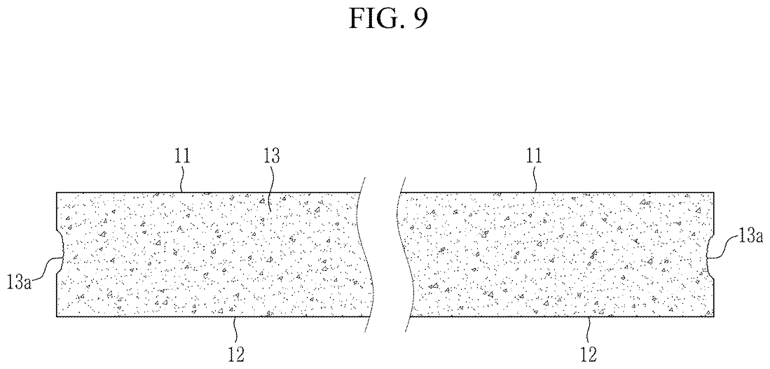

FIG. 8 is a longitudinal cross-sectional view of a semiconductor die along a direction in which the first side surface and the third side surface face each other. FIG. 9 is a diagram illustrating the first side surface.

Referring to FIGS. 8 and 9, the first side surface 13 has a roughness caused by friction with the blade 2 during the dicing process by the blade 2. Each area of the first side surface 13 may have a roughness corresponding to each other over the entire area of the first side surface 13. That is, because the deviation in the roughness between each area of the first side surface 13 has a very small value, it may be understood that the roughness of the first side surface 13 is generally uniform over the entire area. As used herein, roughness means the arithmetic average of the absolute values of the profile height deviations from the mean line recorded within an evaluation length.

A roughness increasing portion 13a in the direction of the first side surface 13 may be formed at the corner of the first side surface 13 located in a direction intersecting the direction in which the first surface 11 and the second surface 12 face each other. The roughness increasing portion 13a in the direction of the first side surface 13 may be formed at a corner of the first side surface 13 in contact with the second side surface 14. In addition, the roughness increasing portion 13a in the direction of the first side surface 13 may be formed at a corner of the first side surface 13 in contact with the fourth side surface 16.

An upper end of the roughness increasing portion 13a in the direction of the first side surface 13 may be spaced apart from the corner of the first surface 11 toward the second surface 12. A lower end of the roughness increasing portion 13a in the direction of the first side surface 13 may be spaced apart from the corner of the second surface 12 toward the first surface 11. At least some area of the roughness increasing portion 13a in the direction of the first side surface 13 may have a shape that is more concavely recessed toward the center of the first side surface 13 than adjacent areas. The roughness of the roughness increasing portion 13a in the direction of the first side surface 13 may have a greater value than that of the remainder of the first side surface 13.

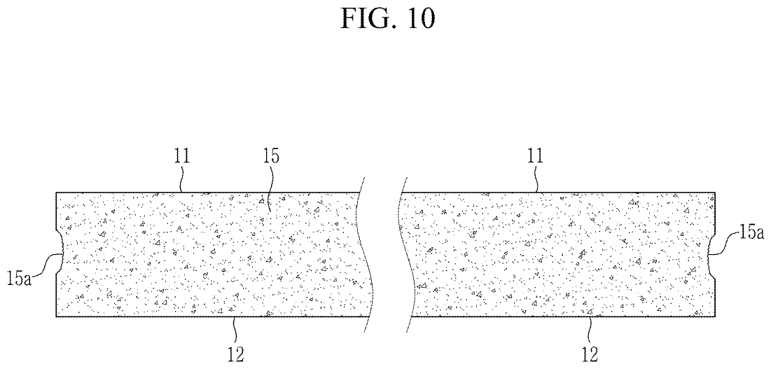

FIG. 10 is a diagram illustrating the third side surface according to some embodiments.

Referring to FIG. 10, the third side surface 15 may have a shape corresponding to the first side surface 13.

The third side surface 15 has a roughness caused by friction with the blade 2 during the dicing process by the blade 2. Each area of the third side surface 15 may have a roughness corresponding to each other across the entire area of the third side surface 15. That is, because the deviation in the roughness between each area of the third side surface 15 has a very small value, it may be understood that the roughness of the third side surface 15 is generally uniform over the entire area. The roughness of the third side surface 15 may correspond to the roughness of the first side surface 13.

A roughness increasing portion 15a in the direction of the third side surface 15 may be formed at the corner of the third side surface 15 located in a direction intersecting the direction in which the first surface 11 and the second surface 12 face each other. The roughness increasing portion 15a in the direction of the third side surface 15 may be formed at a corner of the third side surface 15 in contact with the second side surface 14. In addition, the roughness increasing portion 15a in the direction of the third side surface 15 may be formed at a corner of the third side surface 15 in contact with the fourth side surface 16.

An upper end of the roughness increasing portion 15a in the direction of the third side surface 15 is spaced apart from the corner of the first surface 11 toward the second surface 12. The lower end of the roughness increasing portion 15a in the direction of the third side surface 15 is spaced apart from the corner of the second surface 12 toward the first surface 11. At least some area of the roughness increasing portion 15a in the direction of the third side surface 15 may have a shape that is more concavely recessed toward the center of the third side surface 15 than adjacent areas. The roughness of the roughness increasing portion 15a in the direction of the third side surface 15 may have a greater value than that of the remainder of the third side surface 15.

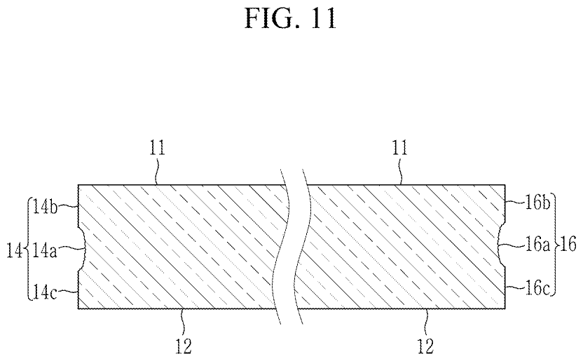

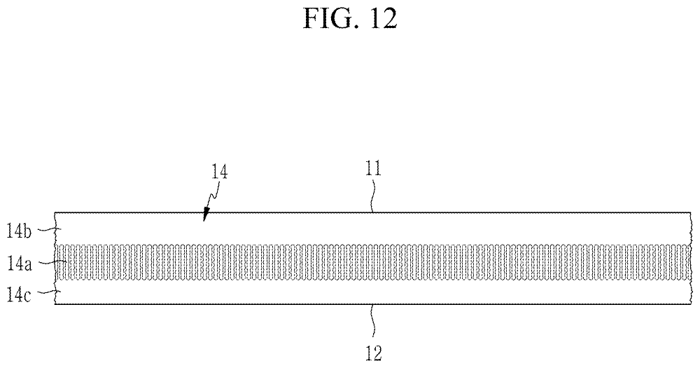

FIG. 11 is a longitudinal cross-sectional view of a semiconductor die along a direction in which the second side surface and the fourth side surface face each other according to some embodiments. FIG. 12 is a diagram illustrating the second side surface according to some embodiments.

Referring to FIGS. 11 and 12, the second side surface 14 has a roughness that varies according to area. The second side surface 14 includes a first crack pattern portion 14a, a first flat portion 14b, and a second flat portion 14c.

The first crack pattern portion 14a is located in the central area of the second side surface 14 based on the direction in which the first surface 11 and the second surface 12 are spaced apart from each other. The first crack pattern portion 14a corresponds to the area FA where the laser L is focused during the dicing process using the laser member 3. That is, during the dicing process using the laser member 3, the crack occurrence area PA is an area created while being exposed to the outside after the separation of adjacent semiconductor dies D is completed. The first crack pattern portion 14a shows a pattern according to cracks generated due to the focus of the laser L. The first crack pattern portion 14a may have a shape in which the first surface 11 and the second surface 12 are directed in a direction spaced apart from each other and a linear crack having a roughness greater than or equal to a predetermined value is arranged along a direction intersecting the direction in which the first surface 11 and the second surface 12 are spaced apart from each other. The roughness of the first crack pattern portion 14a may be greater than that of the first side surface 13. Both ends of the first crack pattern portion 14a may be connected to one of the roughness increasing portions 13a in the direction of the first side surface 13 and one of the roughness increasing portions 15a in the direction of the third side surface 15, respectively.

The first flat portion 14b is located on the end portion of the second side surface 14 adjacent to the first surface 11 based on the direction in which the first surface 11 and the second surface 12 are spaced apart from each other. One end of the first flat portion 14b may contact the first surface 11. The other end of the first flat portion 14b may contact the first crack pattern portion 14a. The first flat portion 14b corresponds to an area located outside the area FA where the laser L is focused during the dicing process using the laser member 3. The first flat portion 14b corresponds to an area in which the semiconductor die D is separated while the crack of the crack occurrence area PA moves around during the expansion process of the tape T. The roughness of the first flat portion 14b is less than that of the first crack pattern portion 14a. The roughness of the first flat portion 14b may be less than that of the first side surface 13.

The second flat portion 14c is located on the end portion of the second side surface 14 adjacent to the second surface 12 based on the direction in which the first surface 11 and the second surface 12 are spaced apart from each other. One end of the second flat portion 14c may contact the second surface 12. The other end of the second flat portion 14c may contact the first crack pattern portion 14a. The second flat portion 14c corresponds to an area located outside the area FA where the laser L is focused during the dicing process using the laser member 3. The second flat portion 14c corresponds to an area in which the semiconductor die D is separated while the crack of the crack occurrence area PA moves around during the expansion process of the tape T. The roughness of the second flat portion 14c is less than that of the first crack pattern portion 14a. The roughness of the second flat portion 14c may be less than that of the first side surface 13. The roughness of the second flat portion 14c may correspond to that of the first flat portion 14b.

The fourth side surface 16 may have a shape corresponding to the second side surface 14. The fourth side surface 16 has a roughness that varies according to area. The fourth side surface 16 includes a second crack pattern portion 16a, a third flat part 16b, and a fourth flat part 16c.

The second crack pattern portion 16a is located in the central area of the fourth side surface 16 based on the direction in which the first surface 11 and the second surface 12 are spaced apart from each other. The second crack pattern portion 16a corresponds to the area FA where the laser L is focused during the dicing process using the laser member 3. That is, during the dicing process using the laser member 3, the crack occurrence area PA is an area created while being exposed to the outside after the separation of adjacent semiconductor dies D is completed. The second crack pattern portion 16a shows a pattern according to cracks generated due to the focus of the laser L. The second crack pattern portion 16a may have a shape in which the first surface 11 and the second surface 12 are directed in the direction spaced apart from each other and a linear crack having a roughness greater than or equal to a predetermined value is arranged along the direction intersecting the direction in which the first surface 11 and the second surface 12 are spaced apart from each other. The roughness of the second crack pattern portion 16a may be greater than that of the first side surface 13. The roughness of the second crack pattern portion 16a may correspond to that of the first crack pattern portion 14a of the second side surface 14.

Both ends of the second crack pattern portion 16a may be connected to one of the roughness increasing portions 13a in the direction of the first side surface 13 and one of the roughness increasing portions 15a in the direction of the third side surface 15, respectively.

The third flat part 16b is located on the end portion of the fourth side surface 16 adjacent to the first surface 11 based on the direction in which the first surface 11 and the second surface 12 are spaced apart from each other. One end of the third flat part 16b may contact the first surface 11. The other end of the third flat part 16b may contact the second crack pattern portion 16a. The third flat part 16b corresponds to an area located outside the area FA where the laser L is focused during the dicing process using the laser member 3. The third flat part 16b corresponds to an area in which the semiconductor die D is separated while the crack of the crack occurrence area PA moves around during the expansion process of the tape T. The roughness of the third flat part 16b is less than that of the second crack pattern portion 16a. The roughness of the third flat part 16b may be less than that of the first side surface 13. The roughness of the third flat part 16b may correspond to that of the first flat portion 14b of the second side surface 14.

The fourth flat part 16c is located on the end portion of the fourth side surface 16 adjacent to the second surface 12 based on the direction in which the first surface 11 and the second surface 12 are spaced apart from each other. One end of the fourth flat part 16c may contact the second surface 12. The other end of the fourth flat part 16c may contact the second crack pattern portion 16a. The fourth flat part 16c corresponds to an area located outside the area FA where the laser L is focused during the dicing process using the laser member 3. The fourth flat part 16c corresponds to an area in which the semiconductor die D is separated while the crack of the crack occurrence area moves around during the expansion process of the tape T. The roughness of the fourth flat part 16c is less than that of the second crack pattern portion 16a. The roughness of the fourth flat part 16c may be less than that of the first side surface 13. The roughness of the fourth flat part 16c may correspond to that of the third flat part 16b. The roughness of the fourth flat part 16c may correspond to that of the second flat portion 14c of the second side surface 14.

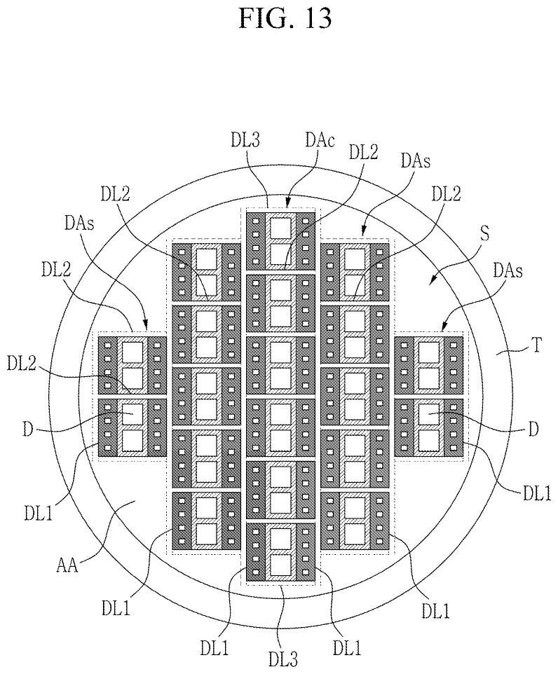

FIG. 13 is a diagram illustrating a substrate on which a substrate dicing method according to further embodiments are performed

Referring to FIG. 13, a substrate S is provided in a state in which a plurality of semiconductor dies D are arranged.

The substrate S may be provided in a state attached to the tape T. The tape T may expand when an external force is applied.

The substrate S includes the plurality of semiconductor die arrays DAc and DAs.

The plurality of semiconductor die arrays DAc and DAs may be arranged side by side with each other. The plurality of semiconductor die arrays DAc and DAs include a center-side semiconductor die array DAc and side semiconductor die arrays DAs.

The center-side semiconductor die array DAc is located across the central area of the substrate S.

Dicing lines DL1, DL2, and DL3 are located around the outer circumferences of each semiconductor die D. The dicing lines DL1, DL2, and DL3 include a first dicing line DL1, a second dicing line DL2, and a third dicing line DL3.

The third dicing lines DL3 are located at both ends of the center-side semiconductor die array DAC in the longitudinal direction, respectively. The third dicing line DL3 is provided to intersect the longitudinal direction of the center-side semiconductor die array DAc. The third dicing line DL3 is provided to intersect the first dicing line DL1. The third dicing line DL3 is provided parallel to the second dicing line DL2.

Other arrangements of the semiconductor die arrays DAc and DAs, the first dicing line DL1 and the second dicing line DL2 are the same as or similar to those of FIG. 1, and therefore, duplicate descriptions thereof will be omitted.

According to the substrate dicing method according to further embodiments, the first dicing line DL1 may be diced using the blade 2. The second dicing line DL2 may be diced using the laser member 3. The third dicing line DL3 may be diced using the blade 2. The third dicing line DL3 may be diced together with the first dicing line DL1.

The dicing method using the blade 2 and the dicing method using the laser member 3 are the same as or similar to the methods described above with reference to FIGS. 2 to 6, and therefore, duplicate descriptions thereof will be omitted.

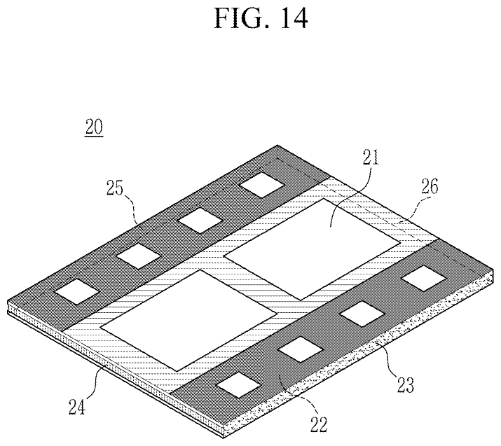

FIG. 14 is a diagram illustrating a semiconductor die located at an end portion of a center-side semiconductor die array in a longitudinal direction among semiconductor dies diced by a substrate dicing method according to further embodiments.

Referring to FIG. 14, the semiconductor die 20 has a first surface 21 and a second surface 22 located to face each other in opposite directions. A first side surface 23, a second side surface 24, a third side surface 25, and a fourth side surface 26 may be located between the first surface 21 and the second surface 22. The first side surface 23 and the third side surface 25 may be located to face each other. The second side surface 24 and the fourth side surface 26 may be located to face each other. An outer side of the first side surface 23 may contact the first surface 21, the second surface 22, the second side surface 24, and the fourth side surface 26, respectively. An outer side of the second side surface 24 may contact the first surface 21, the second surface 22, the first side surface 23, and the third side surface 25, respectively. An outer side of the third side surface 25 may contact the first surface 21, the second surface 22, the second side surface 24, and the fourth side surface 26, respectively. An outer side of the fourth side surface 26 may contact the first surface 21, the second surface 22, the third side surface 25, and the first side surface 23, respectively.

The first side surface 23 and the third side surface 25 are areas facing the first dicing line DL1 in the substrate S described above. Accordingly, the first side surface 23 and the third side surface 25 are surfaces formed through a dicing process using the blade 2.

The second side surface 24 is an area facing the second dicing line DL2 in the above-described substrate S. Accordingly, the second side surface 24 is a surface formed by the dicing process using the laser member 3 and the expansion process of the tape T and the substrate S attached to the tape T.

The fourth side surface 26 is an area facing the third dicing line DL3 in the above-described substrate S. Accordingly, the fourth side surface 26 is a surface formed through the dicing process using the blade 2.

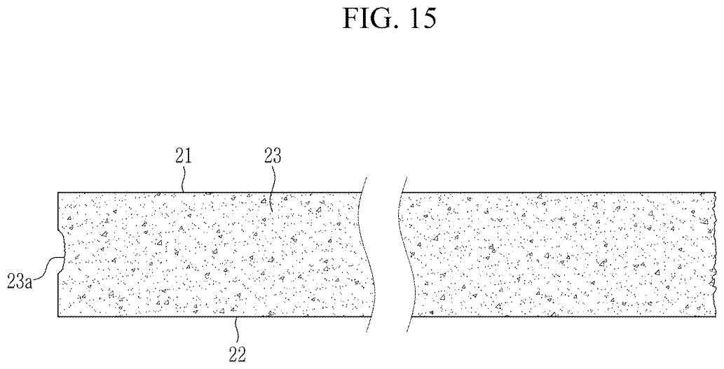

FIG. 15 is a diagram illustrating the first side surface according to some embodiments.

Referring to FIG. 15, the first side surface 23 has a roughness caused by friction with the blade 2 during the dicing process by the blade 2. Each area of the first side surface 23 may have a roughness corresponding to each other over the entire area of the first side surface 23. That is, because the deviation in the roughness between each area of the first side surface 23 has a very small value, it may be understood that the roughness of the first side surface 23 is generally uniform over the entire area.

A roughness increasing portion 23a in the direction of the first side surface 23 may be formed at a corner of the first side surface 23 located in the direction intersecting the direction in which the first surface 21 and the second surface 22 face each other. The roughness increasing portion 23a in the direction of the first side surface 23 may be formed at a corner of the first side surface 23 contacting the second side surface 24.

Except for the roughness increasing portion 23a in the direction of the first side surface 23 being located on one side of the first side surface 23, the structure of the first side surface 23 is the same as or similar to the first side surface 13 of FIGS. 8 and 9, and therefore, duplicate descriptions thereof will be omitted.

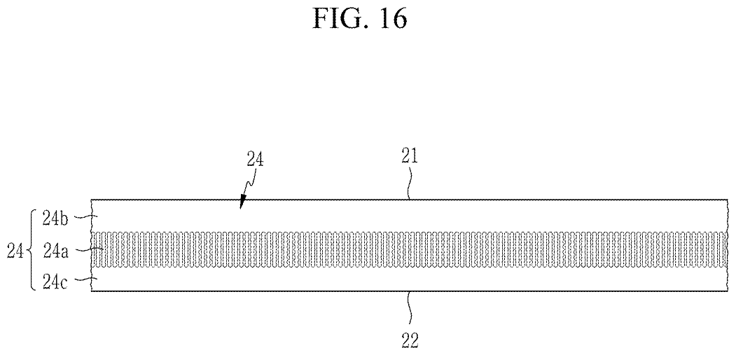

FIG. 16 is a diagram illustrating the second side surface according to some embodiments.

Referring to FIG. 16, the second side surface 24 has a roughness that varies according to area. The second side surface 24 includes a crack pattern portion 24a, a first flat portion 24b, and a second flat portion 24c.

The structure of the second side surface 24 is the same as or similar to that of the second side surface 14 described above with reference to FIG. 12, and therefore, duplicate descriptions thereof will be omitted.

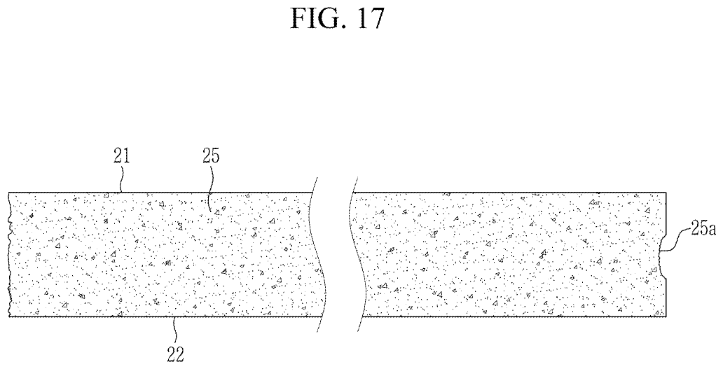

FIG. 17 is a diagram illustrating the third side surface according to some embodiments.

Referring to FIG. 17, the third side surface 25 has a roughness caused by friction with the blade 2 during the dicing process by the blade 2. The third side surface 25 may have a roughness corresponding to each other over the entire area of the third side surface 25. That is, because the deviation in the roughness between each area of the third side surface 25 has a very small value, it may be understood that the roughness of the third side surface 25 is generally uniform over the entire area.

A roughness increasing portion 25a in the direction of the third side surface 25 may be formed at a corner of the third side surface 25 located in the direction intersecting the direction in which the first surface 21 and the second surface 22 face each other. The roughness increasing portion 25a in the direction of the third side surface 25 may be formed at a corner of the third side surface 25 contacting the second side surface 24.

Except for the roughness increasing portion 25a being located on one side of the third side surface 25, the structure of the third side surface 25 is the same as or similar to the third side surface 25 of FIGS. 8 and 10, and therefore, duplicate descriptions thereof will be omitted.

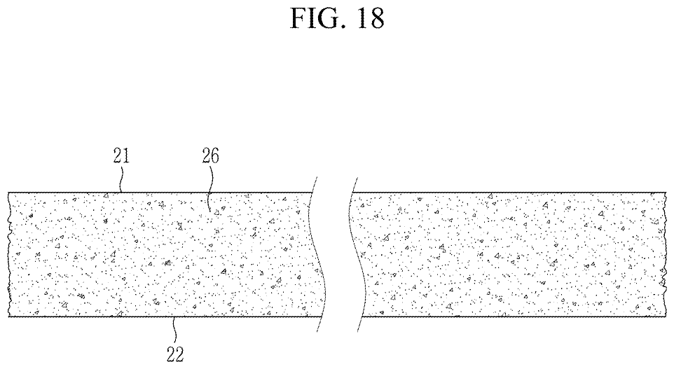

FIG. 18 is a diagram illustrating the fourth side surface according to some embodiments.

Referring to FIG. 18, the fourth side surface 26 has a roughness caused by friction with the blade 2 during the dicing process by the blade 2. Each area of the fourth side surface 26 may have a roughness corresponding to each other over the entire area of the fourth side surface 26. That is, because the deviation of the roughness between each area of the fourth side surface 26 has a very small value, it may be understood that the roughness of the fourth side surface 26 is generally uniform over the entire area. The roughness of the fourth side surface 26 may correspond to that of the first side surface 23.

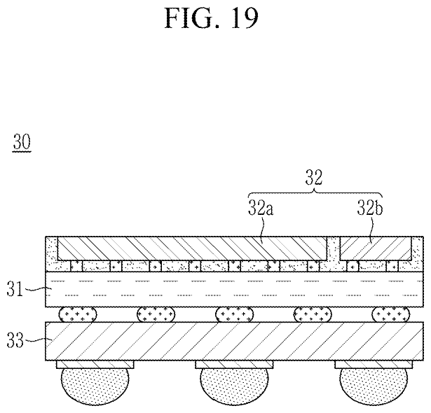

FIG. 19 is a diagram illustrating a semiconductor package according to an embodiment.

Referring to FIG. 19, a semiconductor package 30 includes an interposer 31, a semiconductor chip 32, and a package substrate 33.

The semiconductor chip 32 is mounted on one surface of the interposer 31. The semiconductor chip 32 may include a first semiconductor chip 32a and a second semiconductor chip 32b. The first semiconductor chip 32a may be a logic semiconductor chip such as an application specific integrated circuit (ASIC). The second semiconductor chip 32b may be a memory semiconductor chip 32b such as a high bandwidth memory (HBM).

The interposer 31 is mounted on one side of the package substrate 33.

The interposer 31 may be the semiconductor die 10 of FIG. 7 or the semiconductor die 20 of FIG. 14. The semiconductor chip 32 may be mounted on the semiconductor die 10 of FIG. 7 or the semiconductor die 20 of FIG. 14 where the dicing process has been performed.

Also, the semiconductor chip 32 may be mounted on the semiconductor die D located on the substrate S of FIG. 1 or the substrate S of FIG. 14. Thereafter, the dicing process may be performed on the substrate S of FIG. 1 or the substrate S of FIG. 14 while the semiconductor chip 32 is mounted.

Although embodiments of the present disclosure have been described in detail hereinabove, the scope of the present disclosure is not limited thereto, but may include several modifications and alterations made by those skilled in the art using a basic concept of the present disclosure as defined in the claims.

### DESCRIPTION OF SYMBOLS

S: Substrate
T: Tape
D: Die
DAc: Center-side semiconductor die array
Das: Side semiconductor die array
FA: Laser focus area
PA: Crack occurrence area
2: Blade
3: Laser member
10: Semiconductor die
11: First surface
12: Second surface
13: First side surface
14: Second side surface
15: Third side surface
16: Fourth side surface

What is claimed is:

1. A semiconductor die, comprising:
a first surface;
a second surface opposite to the first surface; and
a first side surface, a second side surface, a third side surface, and a fourth side surface between the first surface and the second surface,
wherein the first side surface faces the third side surface, and the second side surface faces the fourth side surface, and
wherein a roughness of the second side surface varies according to area, and a roughness of at least a portion of the second side surface is greater than that of the first side surface.

2. The semiconductor die of claim 1, wherein:
the second side surface includes:
a crack pattern portion in a central area and extending in a direction in which the first surface and the second surface are spaced apart from each other;
a first flat portion located at an end portion adjacent to the first surface and extending in the direction in which the first surface and the second surface are spaced apart from each other; and
a second flat portion located at an end portion adjacent to the second surface and extending in the direction in which the first surface and the second surface are spaced apart from each other; and
a roughness of the crack pattern portion is greater than that of the first flat portion and that of the second flat portion.

3. The semiconductor die of claim 2, wherein:
the crack pattern portion has a shape in which cracks are arranged along a direction intersecting the direction in which the first surface and the second surface are spaced apart from each other.

4. The semiconductor die of claim 2, wherein:
a roughness of the first flat portion is less than that of the first side surface.

5. The semiconductor die of claim 2, wherein:
a roughness of the second flat portion is less than that of the first side surface.

6. The semiconductor die of claim 1, wherein:
the first side surface includes a roughness increasing portion having a roughness greater than that of the first side surface at a corner that is in contact with the second side surface.

7. The semiconductor die of claim 6, wherein:
at least some area of the roughness increasing portion has a shape that is more concavely recessed toward a center of the first side surface than adjacent areas.

8. The semiconductor die of claim 1, wherein:
each area of the first side surface has a roughness approximately corresponding to each other over an entirety of the first side surface.

9. The semiconductor die of claim 1, wherein:
the first side surface and the third side surface have shapes corresponding to each other.

10. The semiconductor die of claim 1, wherein:
the second side surface and the fourth side surface have shapes corresponding to each other.

11. The semiconductor die of claim 1, wherein:
each area of the fourth side surface has a roughness corresponding to each other over an entire area of the fourth side surface.

12. The semiconductor die of claim 11, wherein:
the roughness of the first side surface approximately corresponds to that of the fourth side surface.

13. A method of dicing a substrate including a plurality of semiconductor die arrays in which a plurality of the semiconductor dies are linearly arranged, a first dicing line parallel to a longitudinal direction of the plurality of semiconductor die arrays and a second dicing line intersecting the longitudinal direction of the plurality of semiconductor die arrays are located on outer circumferences of the plurality of semiconductor dies, and the method comprising:
performing a first dicing operation on the first dicing line using a first process; and
performing a second dicing operation on the second dicing line using a second process that is different from the first process.

14. The method of claim 13, wherein:
the second dicing line is discontinuously located between adjacent semiconductor die arrays among the plurality of semiconductor die arrays.

15. The method of claim 14, wherein:
the second dicing operation is performed using a laser.

16. The method of claim 13, wherein:
the first dicing operation is performed using a blade.

17. A semiconductor package, comprising:
a package substrate;
an interposer mounted on the package substrate; and
a semiconductor chip mounted on the interposer,
wherein the interposer includes:
a first surface;
a second surface located opposite to the first surface; and
a first side surface, a second side surface, a third side surface, and a fourth side surface between the first surface and the second surface, and
wherein the first side surface faces the third side surface, and the second side surface faces the fourth side surface, and
at least some area of the second side surface has cracks therein and has a roughness greater than that of the first side surface, and a roughness of the second side surface varies according to area.

18. The semiconductor package of claim 17, wherein:
the first side surface and the third side surface have a shape corresponding to each other.

19. The semiconductor package of claim 18, wherein:
the second side surface and the fourth side surface have a shape corresponding to each other.

20. The semiconductor package of claim 17, wherein:
the cracks are arranged along a direction intersecting a direction in which the first surface and the second surface are spaced apart from each other.
